(19) United States
(12) Patent Application Publication
(10) Pub. No.: US 2015/0076700 A1
(43) Pub. Date: Mar. 19, 2015

(54) SYSTEM-IN-PACKAGES CONTAINING EMBEDDED SURFACE MOUNT DEVICES AND METHODS FOR THE FABRICATION THEREOF

(71) Applicant: WENG FOONG YAP, PHOENIX, AZ (US)

(72) Inventor: WENG FOONG YAP, PHOENIX, AZ (US)

(21) Appl. No.: 14/030,952

(22) Filed: Sep. 18, 2013

(51) Int. Cl. H01L 25/16; B81B 7/00; H01L 23/00

(52) U.S. Cl. CPC H01L 25/16; H01L 24/95; H01L 24/09; B81B 7/0032
USPC 257/773; 438/106

(57) ABSTRACT

Embodiments of a method for fabricating System-in-Packages (SiPs) are provided, as are embodiments of a SiP. In one embodiment, the method includes producing one or more frontside redistribution layers over a molded panel having a backside and an opposing frontside through which a semiconductor die and a first Surface Mount Device (SMD) are exposed. Material is removed from the backside of the molded panel to expose the first SMD therethrough. A contact array is formed over the frontside of the molded panel and electrically coupled to the semiconductor die and to the first SMD through the frontside redistribution layers. The molded panel is singulated to produce a SiP having a molded body in which the semiconductor die and the first SMD are embedded and through which the first SMD extends.

### TECHNICAL FIELD

Embodiments of the present invention relate generally to microelectronic packaging and, more particularly, to System-in-Packages and methods for fabricating System-in-Packages including surface mount devices, which may be embedded within a molded package body or disposed between stacked package layers.

### BACKGROUND

Fan Out Wafer Level Packaging (FO-WLP) processes are well-known within the semiconductor industry for producing microelectronic packages having peripheral fan-out areas, which enlarge the surface area of the package topside over which a contact array may be formed. In an example of one known FO-WLP approach, commonly referred to as a “Redistributed Chip Packaging” or “RCP” packaging approach, an array of singulated die is encapsulated in a molded panel over which a number of Redistribution Layers (RDL layers) and a Ball Grid Array (BGA) are formed. After formation of the RDL layers and the BGA, the panel is singulated to yield a number of RCP packages each containing a semiconductor die embedded within a molded body. The passive components may be one or more discrete resistors, capacitors, inductors, and/or diodes provided in the form of Surface Mount Devices (SMDs). When integrated into a System-in-Package (SiP) produced utilizing an RCP packaging approach, the SMDs may be positioned horizontally either within an upper portion of the molded package body or over the uppermost RDL layer (e.g., the solder mask layer) adjacent the BGA. It is not uncommon for a single SiP to include multiple die and several discrete resistors, capacitors, inductors, or other SMD devices, depending upon the particular application for which the SiP is designed.

### BRIEF DESCRIPTION OF THE DRAWINGS

At least one example of the present invention will hereinafter be described in conjunction with the following figures, wherein like numerals denote like elements, and:

FIGS. 1-8 are cross-sectional views of a System-in-Package including one or more surface mount devices embedded in and extending through a molded package body, as illustrated at various stages of completion and shown in accordance with an exemplary embodiment of the present invention; and

FIGS. 9-11 are cross-sectional views of three different System-in-Packages each including one or more surface mount devices utilized to provide electrical interconnection between stacked package layers, as illustrated in accordance with further exemplary embodiments of the present invention.

For simplicity and clarity of illustration, the drawing figures illustrate the general manner of construction, and descriptions and details of well-known features and techniques may be omitted to avoid unnecessarily obscuring the exemplary and non-limiting embodiments of the invention described in the subsequent Detailed Description. It should further be understood that features or elements appearing in the accompanying figures are not necessarily drawn to scale unless otherwise stated. For example, the dimensions of certain elements or regions in the figures may be exaggerated relative to other elements or regions to improve understanding of embodiments of the invention.

### DETAILED DESCRIPTION

The following Detailed Description is merely exemplary in nature and is not intended to limit the invention or the application and uses of the invention. Any implementation described herein as exemplary is not necessarily to be construed as preferred or advantageous over other implementations. Furthermore, there is no intention to be bound by any theory presented in the preceding Background or the following Detailed Description.

Terms such as “first,” “second,” “third,” “fourth,” and the like, if appearing in the description and the subsequent claims, may be utilized to distinguish between similar elements and are not necessarily used to indicate a particular sequential or chronological order. Such terms may thus be used interchangeably and that embodiments of the invention are capable of operation in sequences other than those illustrated or otherwise described herein. Furthermore, terms such as “comprise,” “include,” “have,” and the like are intended to cover non-exclusive inclusions, such that a process, method, article, or apparatus that comprises a list of elements is not necessarily limited to those elements, but may include other elements not expressly listed or inherent to such process, method, article, or apparatus. The term “coupled,” as appearing herein, is defined as directly or indirectly connected in an electrical or non-electrical manner. Furthermore, the terms “substantial” and “substantially” are utilized to indicate that a particular feature or condition is sufficient to accomplish a stated purpose in a practical manner and that minor imperfections or variations, if any, are not significant for the stated purpose.

As appearing herein, the term “microelectronic component” is utilized in a broad sense to refer to an electronic device, element, or structure produced on a relatively small scale and amenable to packaging in the below-described manner. Microelectronic components include, but are not limited to, integrated circuits formed on semiconductor die, Microelectromechanical Systems (MEMS) devices, passive electronic components (e.g., a discrete resistor, capacitor, inductor, or diode), optical devices, and other small scale electronic devices capable of providing processing, memory, sensing, radiofrequency, optical, and actuator functionalities, to list but a few examples. The term “System-in-Package” and the corresponding acronym “SiP” are further utilized herein to refer to a microelectronic package including at least one semiconductor die packaged with at least one passive microelectronic component, such as a surface mount device. The term “Surface Mount Device” and the corresponding acronym “SMD” are still further utilized herein to refer to a discrete microelectronic device directly mountable on the surface of a substrate, such as a printed circuit board, having electrical points-of-contact with which the SMD may be placed in ohmic contact. A non-exhaustive list of SMDs includes discrete resistors, capacitors, inductors, diodes, and the like. In this regard, the SMDs contained with the SiPs produced pursuant to the below-described fabrication method conveniently (but need not always) assume the form of two terminal packages having generally rectangular or square-shaped bodies, such as chip resistors, chip capacitors, and/or chip inductors having opposing end terminals. The term “terminal” may be utilized herein to refer to a node, lead, or other point-of-contact provided on a microelectronic device, such as an SMD. Finally, the term “about 0 ohm (Ω)” is defined herein as a resistance of less than 0.1Ω.

The following describes embodiments of a method for producing SiPs wherein SMDs, such as discrete resistors, capacitors, inductors, and/or diodes, are placed in ohmic contact with electrically-conductive members located on opposing sides of package body or located within different stacked package layers. In many cases, the SMDs are utilized to provide their traditional or intended function; e.g., the provision of a known resistance, capacitance, inductance, or the like. Additionally or alternatively, the embedded SMDs may also provide a new or heretofore unrealized function, namely, the provision of low (e.g., about 0Ω) resistance signal paths through the package body and/or between package layers. In this manner, the embedded SMDs may effectively replace other structures or features traditionally utilized to provide signal routing through the package body (e.g., through package vias) and/or between package layers (e.g., solder balls). In certain cases, a single SMD may be utilized to provide both of these functionalities; e.g., a single chip resistor, capacitor, or inductor may provide a known resistance, capacitance, or inductance, respectively, while also providing one or more low resistance signal paths through the package body or between stacked package layers. The SMDs embedded within a given SiP may be positioned in horizontal orientations, vertical orientations, or a combination thereof. Advantageously, by embedding multiple SMDs in a molded package body in a vertical orientation, a greater number of SMDs can be integrated into the SiP while reducing the planform dimensions or footprint of the SiP.

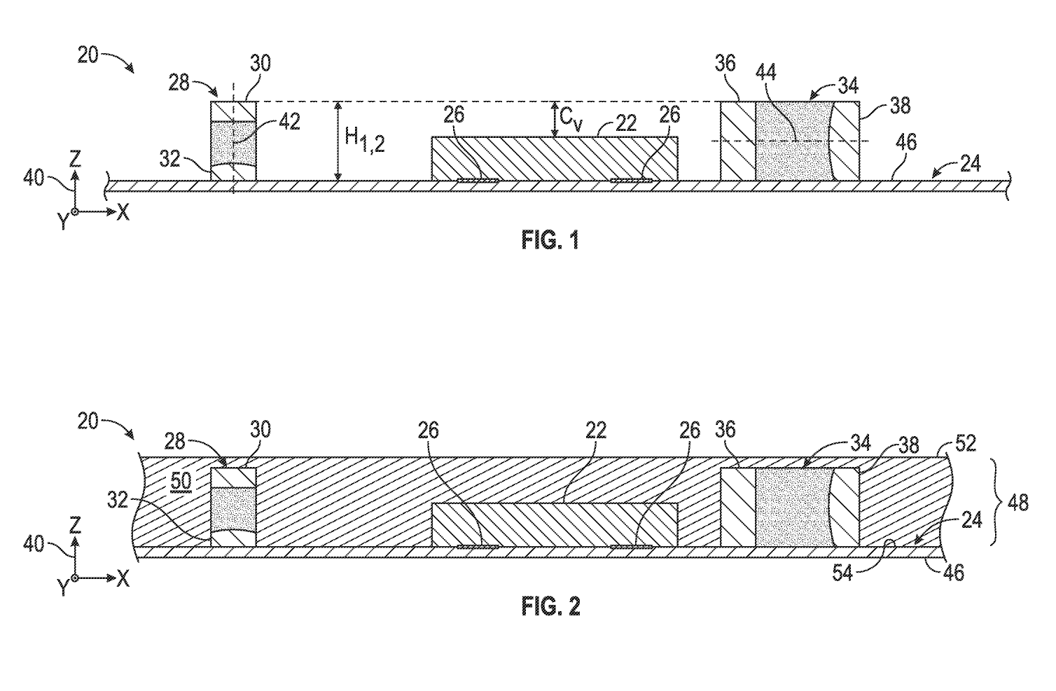

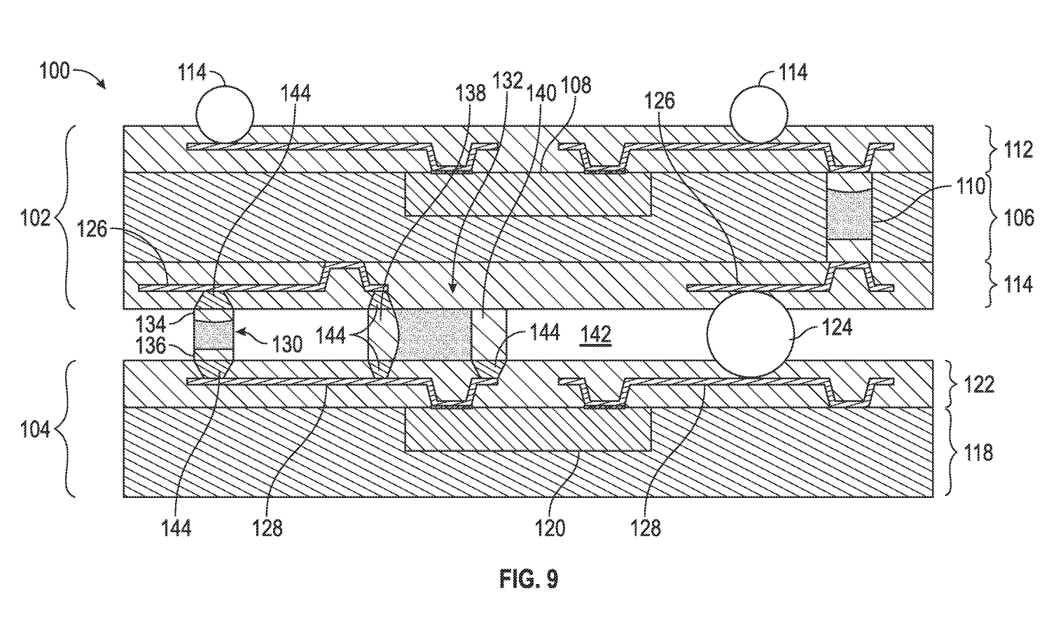

FIGS. 1-8 are cross-sectional views of a SiP 20, as illustrated at various stages of manufacture and shown in accordance with an exemplary embodiment of the present invention. In this particular example, SiP 20 is produced utilizing a molded panel process wherein a molded panel (e.g., molded panel 48 partially shown in FIGS. 2-7) is produced, processed, and then singulated in to yield SiP 20 in its completed form along with a number of additional completed SiPs. The other SiPs produced pursuant to the below-described fabrication process may or may not be substantially identical to SiP 20; however, the process steps described herein will typically be performed globally across the molded panel and are consequently generally descriptive of the processing of the panel, as a whole. In further embodiments, the SiP can be produced utilizing other non-molded panel fabrication techniques, such as those described below in conjunction with FIGS. 9-11.

Referring initially to FIG. 1, production of SiP 20 commences with the placement of a number of microelectronic devices in predetermined groupings on a temporary substrate 24 (partially shown). Each grouping may include at least one semiconductor die and at least one SMD. Only one microelectronic device grouping is shown in FIG. 1, namely, the grouping of devices to be included within SiP 20, when completed. This grouping includes a semiconductor die 22, a first SMD 28, and a second SMD 34. Additional semiconductor die and/or additional SMDs may also be included within the other regions of SiP 20, which cannot be seen in the cross-sectional view shown in FIG. 1; e.g., in one embodiment, a relatively large number of SMDs may be spaced around the outer periphery of die 22 in addition to SMDs 28 and 34. As indicated above, only a relatively small portion of temporary substrate 24 supporting those devices included within SiP 20 (e.g., semiconductor die 22, SMD 28, and SMD 34) is shown in FIG. 1 to avoid unnecessarily obscuring the drawings. It will be appreciated, however, that temporary substrate 24 will typically be considerably larger than the illustrated portion, and that a relatively large number of semiconductor die and SMDs may be distributed over the upper surface of substrate 24 in various other device groupings to be contained with the other SiPs produced in parallel with SiP 20.

Semiconductor die 22, SMD 28, and SMD 34 each include a number of contacts or terminals. In the case of semiconductor die 22, the contacts assume the form of bond pads 26 disposed on the upper or frontside surface of die 22. In the case of SMDs 28 and 34, the contacts may assume different forms and dispositions depending upon the particular type of SMD employed. In the illustrated example, SMDs 28 and 34 are two terminal devices each having a generally rectangular body, when viewed from the side, top, or bottom; and which is flanked by electrically-conductive end terminals extending beyond the body in at least one lateral direction. In this regard, SMD 28 may include opposing end terminals 30 and 32, while SMD 34 includes opposing end terminals 36 and 38. SMDs 28 and 34 may be discrete resistors, capacitors, inductors, or a combination thereof. In one embodiment, SMDs 28 and 34 may assume the form of discrete capacitors (commonly referred to as “chip capacitors” or, more simply, “chip caps”) each including an electrically-insulative (e.g., ceramic) body disposed between two electrically-conductive end pieces; i.e., terminals 30 and 32 in the case of SMD 28, and terminals 36 and 38 in the case of SMD 34. In other embodiments, one or both of SMDs 28 and 34 may assume the form of a two-terminal chip inductor or a two-terminal chip resistor having the generally rectangular form factor illustrated in FIG. 1. The SMD terminals may be composed of any electrically-conductive material and may have various different surface finishes, such as tin, copper, gold, nickel, conductive epoxy, palladium, silver, and lead-based finishes, to list but a few examples.

When placed onto temporary substrate 24, semiconductor die 22 is inverted and positioned facedown such that bond pads 26 of die 22 are placed in contact with the upper surface of substrate 24. By comparison, SMD 28 is positioned in a vertical orientation such that terminal 32 is placed in contact with the upper surface of substrate 24; while terminal 30 is located above substrate 24, as taken along an axis substantially orthogonal to the frontside or backside of the subsequently-produced package body (corresponding to the “Z-axis” identified in FIG. 1 by coordinate legend 40). Stated differently, SMD 28 has been positioned such that its longitudinal axis (represented in FIG. 1 by dashed line 42) is substantially orthogonal to the upper surface of temporary substrate 24. For this reason, SMD 28 may be referred to more fully hereafter as “vertically-orientated SMD 28.” By comparison, SMD 34 has been placed in a horizontal orientation such that terminals 36 and 38 both contact the upper surface of substrate 24 and such that its longitudinal axis (represented in FIG. 1 by dashed line 44) is substantially parallel to the upper surface of temporary substrate 24. SMD 34 may thus be referred to more fully hereafter as “horizontally-orientated SMD 34.”

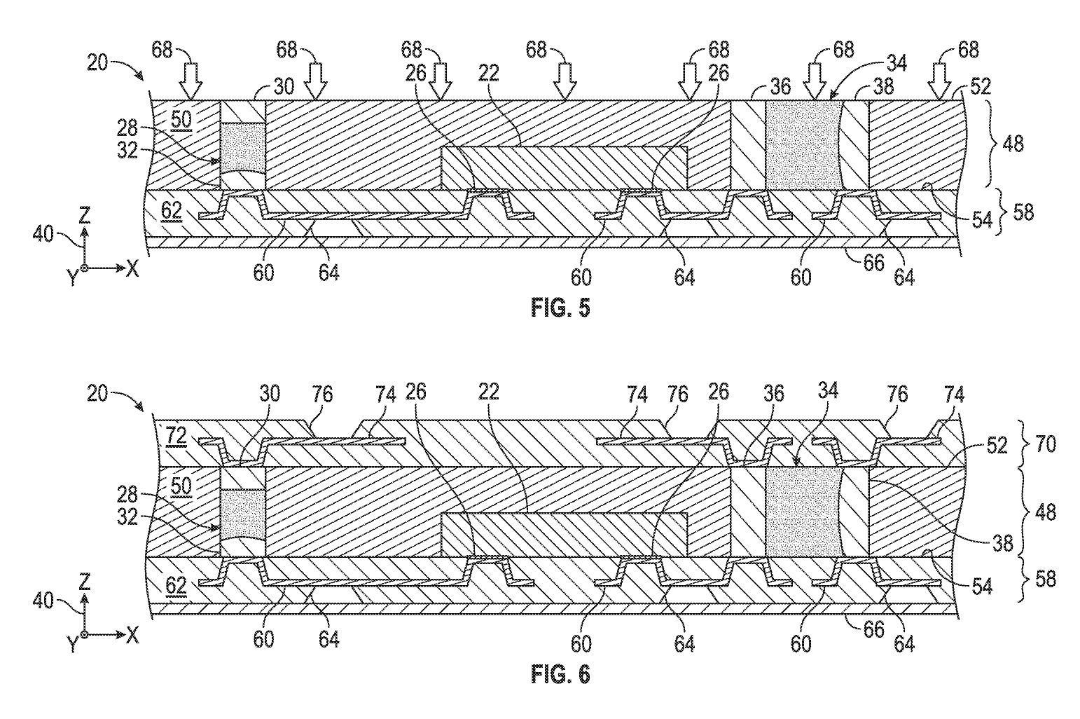

Vertically-orientated SMD 28 and horizontally-orientated SMD 34 each have a thickness greater than that of semiconductor die 22, as taken through the package thickness or along an axis orthogonal to the package frontside or backside (corresponding to the “Z-axis” in FIG. 1). For the purpose of this document, the thicknesses of SMD 28, SMD 34, and other embedded SMDs are considered after placement in their packaged orientation and will be consequently be referred to below as the “packaged height.” In the illustrated example, the packaged heights of SMD 28 and SMD 34 are substantially equivalent (as indicated in FIG. 1 by double-headed arrow “H_{1,2}”). Furthermore, due to the disparity in height between die 22 and the packaged height of SMDs 28 and 34, a vertical clearance is provided between die 22, SMD 28, and SMD 34 (represented by double-headed arrow “C_{V}”). This clearance allows material to be removed from the backside of the panel in which semiconductor die 22, SMD 28, and SMD 34 are later embedded (e.g., molded panel 48 described below in conjunction with FIGS. 2-7) without damaging die 22. SMDs 28 and 34 may thus be chosen such that their respective packaged heights are substantially equivalent or slightly greater than the desired final thickness of the panel body, as described more fully below in conjunction with FIG. 5.

Temporary substrate 24 can be any body, structure, or platform suitable for supporting die 22, vertically-orientated SMD 28, horizontally-orientated SMD 34, and the other non-illustrated microelectronic devices during panel encapsulation (also commonly referred to as “panelization” or “overmolding”). In one embodiment, temporary substrate 24 is a taped molded frame, which includes a soft tape adhesive layer 46 on which semiconductor die 22, vertically-orientated SMD 28, and horizontally-orientated SMD 34 are placed. A non-illustrated mold frame, which has a central cavity or opening therein, is positioned over tape layer 46 and around the semiconductor die disposed thereon. An electrically-insulative encapsulant or mold compound, such as a silica-filled epoxy, is dispensed into the cavity of the mold frame. The encapsulant flows over and around die 22, SMD 28, and SMD 34 and the other devices placed on tape layer 46. The encapsulant may then solidified by thermal curing (e.g., heating in a partially-evacuated chamber) to yield a solid panel in which die 22, SMD 28, SMD 34, and the other non-illustrated microelectronic devices are embedded. The panel is conveniently produced as a relatively thin, disc-shaped body or mass having a generally circular planform geometry; however, the panel body can be fabricated to have any desired shape and dimensions. In other embodiments, the panel can be produced utilizing various other known fabrication techniques including, for example, compression molding and lamination processes.

FIG. 2 illustrates a portion of a molded panel 48 that may be produced pursuant to the above-described encapsulation process. While only the portion of molded panel 48 containing semiconductor die 22, vertically-orientated SMD 28, and horizontally-orientated SMD 34 is shown in FIG. 2 for clarity, it will be understood that molded panel 48 will typically be considerably larger than the illustrated portion of panel 48 and will contain various other encapsulated microelectronic components, such as other die placed in predetermined groupings with other SMDs similar to vertically-orientated SMD 28 and horizontally-orientated SMD 34. As can be seen in FIG. 2, molded panel 48 includes a panel body 50 having a backside surface 52 and an opposing frontside surface 54. Terminal 32 of vertically-orientated SMD 28, bond pads 26 of semiconductor die 22, and terminals 26 and 38 of horizontally-orientated SMD 34 are exposed through frontside surface 54 of molded panel 48. However, at this juncture in the fabrication process, semiconductor die 22, vertically-orientated SMD 28, and horizontally-orientated SMD 34 are covered by a relatively thin layer of overburden in the region of panel body 50 opposite frontside 54 and are, thus, not exposed through backside 52 of panel 48.

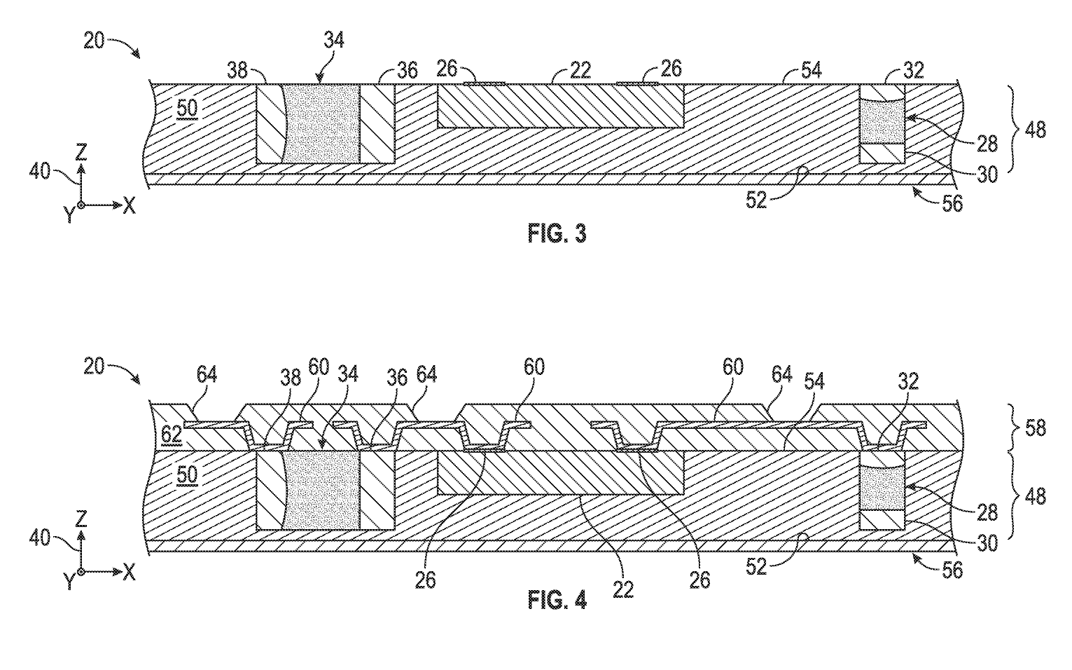

Referring next to FIG. 3, molded panel 48 may be thermally released or otherwise removed from temporary substrate 24 to reveal frontside surface 54 of panel body 50. Additional processing of molded panel 48 may be performed after release from substrate 24; e.g., panel 48 may be cleaned to remove any adhesive residue present thereon, further curing of panel 48 may be performed by oven bake, and so on. Molded panel 48 is then inverted and attached to a support structure, such as a ceramic carrier 56. With frontside 54 of panel 48 now facing upwards, one or more frontside RDL layers (also commonly referred to as “build-up layers” or “metal levels”) may be built over panel 48. For example, as shown in FIG. 4, a number of frontside RDL layers 58 may be produced over frontside 54 of panel 48, which include one or more electrically-conductive interconnect lines 60 formed in a body 62 of dielectric material. Dielectric body 62 may be formed as a number of successively-deposited (e.g., spun-on) dielectric layers, and interconnect lines 60 may be formed within dielectric body 62 utilizing well-known lithographical patterning and conductive material (e.g., copper) deposition techniques. Again, it will be noted that only a relatively small portion of frontside RDL layers 58 is shown in FIG. 4 and that RDL layers 58 will typically be formed over the entire frontside 54 of panel 48 such that at least one frontside interconnect line 60 is formed in ohmic contact with all semiconductor die and SMDs embedded within panel 48.

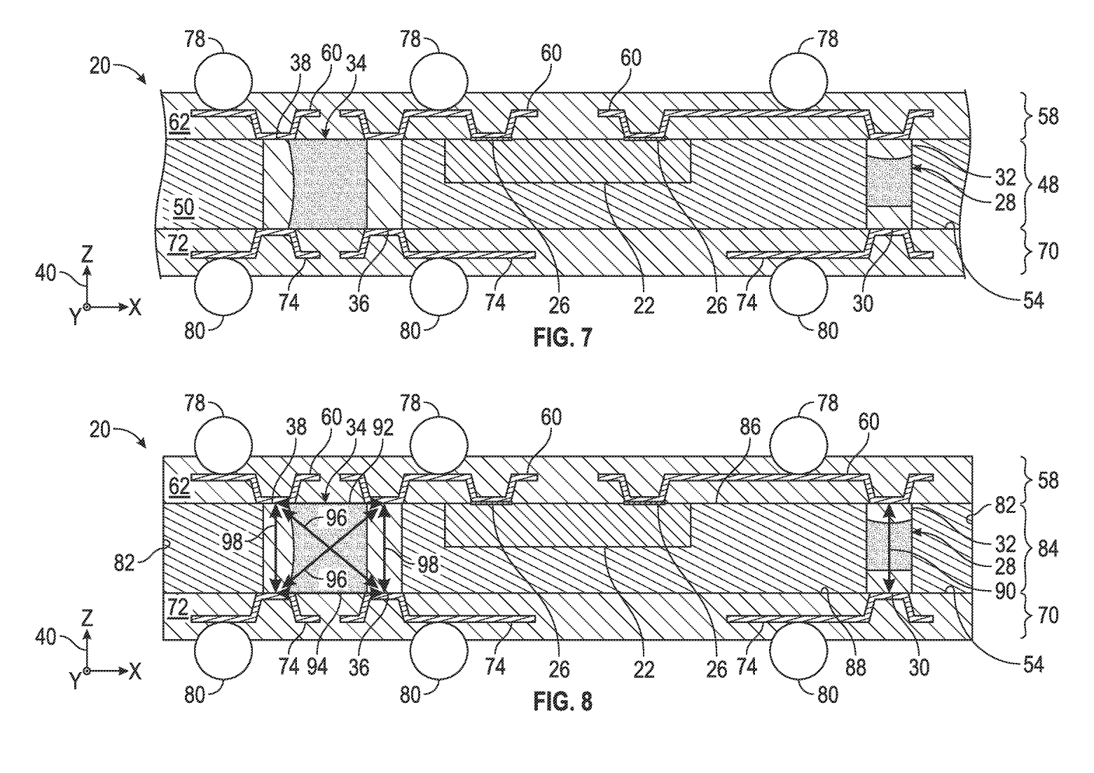

Frontside interconnect lines 60 may comprise various metal traces, vias, metal plugs, and/or the like, which collectively provide electrically-conductive paths between the upper surface of frontside RDL layers 58 and semiconductor die 22, vertically-orientated SMD 28, and horizontally-orientated SMD 34 embedded within panel 48. In this regard, interconnect lines 60 may be formed in ohmic contact with terminal 32 of vertically-orientated SMD 28, bond pads 26 of die 22, and terminals 36 and 38 of horizontally-orientated SMD 34. After formation of frontside RDL layers 58, trenches or openings 64 may be formed in the uppermost RDL layer (e.g., a capping, passivation, or solder mask layer) by lithographical patterning to expose selected regions of frontside interconnect lines 60. A frontside contact array, such as a BGA, may then be produced over the frontside of partially-completed SiP 20 and in ohmic contact with the exposed regions of interconnect lines 60. Alternatively, a frontside contact array may not be produced until after build-up of one or more backside RDL layers, as described below in conjunction with FIGS. 6 and 7.

With reference to FIG. 5, molded panel 48 is next removed from carrier 56, inverted, and attached to a new ceramic carrier 66 or other support structure. Afterwards, material is removed from backside 52 of molded panel 48 to reveal SMDs 28 and 34 therethrough. In certain embodiments, a relatively limited amount of material can be selectively removed by, for example, localized grinding to create small cavities in backside 52 exposing SMD 28 and SMD 34 (and some or all of the other SMDs embedded molded panel 48). Alternatively, as indicated in FIG. 5 by arrows 68, a global material removal process is performed can be performed during which material is removed from across the entire backside 52 of panel 48 to expose SMDs 28 and 34. Specifically, material may be globally removed from across backside 52 of panel 48 to expose the outer face or endwall of terminal 30 of vertically-orientated SMD 28, as well as upper edges portion of terminals 36 and 38 of horizontally-orientated SMD 34. Such a global material removal process can be carried-out utilizing any technique suitable for removing a predetermined thickness from molded panel 48 within acceptable tolerances. In a preferred embodiments, either a grinding process or chemical mechanical planarization (“CMP”) process is employed.

Pursuant to the above-descried material removal process, molded panel 48 may be imparted with a final thickness between about 100 and about 1000 microns (m) and, preferably, between about 200 and about 700 μm. In further embodiments, the final thickness of panel 48 may be greater than or less than the aforementioned ranges. Furthermore, it is preferred, although by no means necessary, that the material removal process imparts backside 52 of panel 48 with a substantially planar topology; that is, a surface roughness of less than about 30 μm, preferably less than about 1 μm, and, still more preferably, less than about 0.5 μm. If desired, the backside material removal process can be carried-out in multiple steps or stages. For example, in one implementation of the fabrication process, an initial bulk removal grinding step may first be carried-out utilizing a pad or paper having a relatively coarse grit, and followed by a final grinding step performed utilizing a pad or paper having a relatively fine grit to impart molded panel 48 with a relatively planar surface finish. In embodiments wherein the material removal process imparts panel 48 with substantially planar backside surface (again, defined as a surface having a roughness or feature height less than about 30 μm), the material removal process may also be referred to as a “planarization process” herein.

A certain amount of material may be removed from the SMD terminals exposed through backside 52 of panel 48 during the above-described material removal process. However, a certain amount of material removal from the SMD terminals is permissible within controlled limits as terminals 30, 36, and 38 will typically be relatively thick (e.g., >20 μm), as taken along the longitudinal axes of SMDs 28 and 34 (identified in FIG. 1); and can be partially removed via grinding or polishing without damaging the bodies of SMDs 28 and 34. Additionally, with respect to horizontally-orientated SMD 34, it will be noted that opposing end terminals 36 and 38 extend laterally beyond the body of SMD 34, as taken along an axis orthogonal to frontside 54 or backside 52 of panel 48 (again, identified as the “Z-axis” in FIG. 5; and as considered with SMD 34 in its packaged orientation). Thus, an outer peripheral portion of terminals 36 and 38 can be removed during planarization without damaging the body of SMD 34.

As previously stated, SMD 28, 34, and the other non-illustrated SMDs embedded within molded panel 48 may be chosen such that their respective packaged heights are substantially equivalent to the desired final thickness of panel 48 and, therefore, the final thickness of the molded package bodies produced pursuant to singulation of panel 48 (described below in conjunction with FIG. 8). In this regard, it will be noted that the embedded SMDs need not have an initial packaged height precisely equivalent to the final panel thickness. Instead, as some amount of material may be removed from the SMD terminals during planarization, one or more SMDs may be chosen to have an initial packaged height slightly greater than the panel thickness; although it will be appreciated that the packaged heights of the SMDs may be brought into substantial conformity with the panel thickness after the above-described material removal process. Advantageously, many different SMDs are commercially available as off-the-shelf components having dimensions suitable for integration into a molded panel of the type described above. In further embodiments, some or all of the SMDs embedded within panel 48 may have a packaged height different than the final panel thickness.

One or more backside RDL layers 70 may be formed over the newly-planarized backside 52 of molded panel 48 and, therefore, over semiconductor die 22, vertically-orientated SMD 28, horizontally-orientated SMD 34, and the microelectronic devices embedded within the other, non-illustrated regions of panel 48. Backside RDL layers 70 may be produced to include a dielectric body 72, which may be formed as one or more spun-on or otherwise deposited dielectric layers. Electrically-conductive paths or interconnect lines 74 are formed within dielectric body 72 utilizing, for example, lithographical patterning and conductive material deposition processes of the type described above. Backside interconnect lines 74 are formed in ohmic contact with terminal 32 of vertically-orientated SMD 28 and terminals 36 and 38 of horizontally-orientated SMD 34. Considering this, it will be appreciated that SMD 28 and SMD 34 are each electrically interconnected across the body 50 of molded panel 48, albeit in different manners as discussed below. After formation of the backside RDL layers 70, trenches or openings 76 may be created within the final or outermost dielectric layer of backside RDL layers 70 by lithographical patterning to expose selected regions of interconnect lines 74. The resultant structure is shown in FIG. 6.

A frontside contact array and/or a backside contact array may now be formed over partially-completed SiP 20, as well as over the other partially-completed SiPs fabricated over the non-illustrated regions of molded panel 48. With respect to partially-completed SiP 20, specifically, a frontside contact array 78 and backside contact array 80 may be formed over frontside RDL layers 58 and backside RDL layers 70, respectively, as generally shown in FIG. 7. Frontside contact array 78 may be produced as a first BGA including a plurality of solder balls deposited into openings 64 (FIGS. 4-6) formed in the outermost dielectric layer 70 (e.g., a passivation, capping, or solder mask layer) of frontside RDL layers 58 and in ohmic contact with frontside interconnect lines 60. Similarly, backside contact array 80 may be produced as a second BGA including a plurality of solder balls deposited into openings 76 (FIG. 7) formed in the outermost dielectric layer of backside RDL layers 70 and in ohmic contact with backside interconnect lines 74.

While frontside and backside contact arrays 78 and 80 assume the form of BGAs in the illustrated example, contact arrays 78 and 80 may assume other forms suitable for providing externally-accessible points-of-contact to the interconnect lines embedded within the frontside RDL layers 58 and backside RDL layers 70. For example, in further embodiments, the frontside and/or backside contact array may comprise externally-exposed bond pads in ohmic contact with the interconnect lines formed in the frontside and/or backside RDL layers; externally-exposed portions of the frontside and/or backside RDL interconnect lines; or electronically-conductive bodies formed in contact with the frontside and/or backside interconnect lines other than solder balls, such as plated pillars or bodies of electrically-conductive paste. Furthermore, while SiP 20 is produced to include backside RDL layers 70 and a backside contact array 80 in the illustrated example, this need not always be the case. Instead, in further embodiments, the fabrication method may conclude after the backside planarization process described above in conjunction with FIG. 5 and corresponding exposure of the SMD terminals; e.g., terminal 30 of SMD 28 and terminals 36 and 38 of SMD 34. In such implementations, electrical connection to the exposed SMD terminals may occur when SiP 20 is mounted on a printed circuit board or otherwise installed into a larger system or electronic device.

Fabrication of SiP 20 and the other SiPs produced in parallel with SiP 20 concludes with the singulation of molded panel 48 into multiple discrete pieces. Singulation of panel 48 is conveniently preformed utilizing a dicing saw; however, any process suitable for separating panel 48 into multiple, discrete pieces can be utilized, such as laser cutting. FIG. 8 illustrates SiP 20 in a completed state after separation from panel 48. The singulated piece of molded panel 48 included within completed SiP 20 is identified by reference numeral “84” in FIG. 8 and is referred to below as “molded package body 84.” Molded package body 84 includes vertical package sidewalls 82, which have been defined by singulation of panel 48. Completed SiP 20 includes at least two SMDs (i.e., SMDs 28 and 34), which have been embedded within molded package body 84 and which extend fully through package body 84; that is, from the frontside 86 of package body 84 to the backside 88 thereof. SMDs 28 and 34 may be interconnected with semiconductor die 22 through frontside interconnect lines 60. Additionally, die 22 may be connected to frontside contact array 78 through frontside interconnect lines 60 and, possibly, to backside contact array 80 through frontside interconnect lines 60, one or both of SMDs 28 and 34 (or other non-illustrated through package vias), and through backside interconnect lines 74.

With continued reference to FIG. 8, SMD 34 is positioned in a horizontal orientation such that outer edges of both of its opposing end terminals (i.e., terminals 36 and 38) are exposed through frontside 86 and through backside 88 of package body 84. In contrast, SMD 28 is positioned in a vertical orientation such that one of its end terminals (i.e., terminal 32) is exposed through frontside 86 of molded package body 84, while its opposing end terminal (i.e., terminal 30) is exposed through backside 88 of package body 84. In view of its vertical orientation, the longitudinal axis of SMD 28 is substantially orthogonal to frontside 86 or backside 88 of package body 84; and the opposing end terminals of SMD 28 vertically overlap, as taken along an axis orthogonal to frontside 86 or backside 88 of package body 84. Finally, it will be noted that the respective packaged heights of SMDs 28 and 34 are substantially equivalent to the thickness of package body 84, as taken through the package thickness or along an axis substantially orthogonal to frontside 86 or backside 88 of package body 84 (corresponding to the Z-axis in FIG. 8).

As will be gathered from the foregoing description, SMDs 28 and 34 are embedded within package body 84 in different orientations such that the longitudinal axes of SMDs 28 and 34 (identified in FIG. 1) extend within different orthogonal planes. In further embodiments, SiP 20 may include only vertically-oriented SMDs or only horizontally-oriented SMDs. Each SMD orientation provides different advantages. Consider, for example, the vertical orientation of SMD 28. By placing SMD 28 in such a vertical orientation (along with any other non-illustrated SMDs having packaged heights greater than their packaged widths), the planform dimensions or X-Y footprint of the SMDs can be reduced. Stated differently, such a reduction in SMD footprint can be realized in instances wherein SMD has a generally rectangular body and is vertically oriented such that the height of the SMD (as taken along an axis orthogonal to the frontside of the molded body containing the packaged SMD) exceeds its width (as taken along an axis parallel to the frontside of the molded body containing the packaged SMD). As a result, a greater number of SMDs can be integrated into SiP 20, while maintaining or decreasing the planform dimensions of SiP 20 to achieve higher device densities. Additionally, in embodiments wherein the planform dimensions of SiP 20 are reduced, the volume of the mold compound and other materials required to produce SiP 20 may also be decreased resulting in lower manufacturing costs. These benefits may be realized while SMD 28 (and any other vertically-oriented SMDs included within SiP 20) continues to provide its traditional or dedicated function (e.g., the provision of a known capacitance, resistance, or inductance), albeit across a vertical electrically-conductive path provided through package body 84 (represented in FIG. 8 by double-headed arrow 90). In further embodiments, a discrete resistor having a resistance of about 0Ω and may be utilized as vertically-orientated SMD 28 to provide a low resistance signal path through package body 84.

Horizontally-orientated SMD 34 extends through package body 84 such that the upper and lower surfaces of SMD 34 are substantially coplanar with frontside 86 and backside 88 of body 84, respectively. Such a positioning allows SMD 34 to provide a dual functionality. In particular, SMD 34 may provide its traditional or dedicated function (e.g., the provision of a known capacitance, resistance, or inductance) between contact points or nodes in frontside RDL layers 58 (represented in FIG. 8 by double-headed arrow 92), between contact points or nodes in backside RDL layers 70 (represented by double-headed arrow 94), and/or between first and second contact points or nodes located in frontside RDL layers 58 and backside RDL layers 70, respectively (represented by double-headed arrows 96). Additionally or alternatively, SMD 34 may provide a new functionality, namely, the provision of one or more electrically-conductive paths through package body 84 between opposing contact points provided in RDL layers 58 and 70 (represented by double-headed arrows 98). In this manner, end terminal 36 and/or end terminal 38 of SMD 34 may effectively function as a through package via to provide additional signal routing between the package topside and bottomside.

There has thus been described multiple exemplary embodiments of a fabrication process suitable for producing one or more SiPs each including at least one embedded SMD, which extends through a molded package body produced in accordance with a molded panel packaging approach similar to an RCP packaging approach. In certain embodiments, the embedded SMD may be vertically oriented to reduce the X-Y footprint of the SMD and, more generally, the X-Y footprint of the SiP. The SMD may provide its typical functionality and/or may also provide one or more signal paths through the package body, as described above. In still further embodiments, SiPs can be produced wherein one or more embedded SMDs (whether positioned horizontally or vertically) provide electrical interconnectivity between stacked package layers. In this case, the SiP may assume the form of a “Package-on-Package” or “PoP” device having two or more package layers. The package layers may be produced utilizing various different manufacturing techniques, and a given SiP may include multiple package layers each produced utilizing a different packaging technique. Several examples of SiPs including embedded SMDs electrically coupled or bridged across stacked package layers will now be described in conjunction with FIGS. 9-11.

FIG. 9 is a simplified cross-sectional view of a SiP 100, as illustrated in accordance with a further exemplary embodiment of the present invention. In this example, SiP 100 includes two stacked sub-packages or package layers 102 and 104, which have each been produced utilizing a molded panel packaging process of the type described above. In the illustrated example, upper package layer 102 is produced to include a molded package body 106, a die 108 embedded within body 106, a vertically-oriented SMD 110 embedded within body 106, frontside RDL layers 112, a frontside contact array 114, and backside RDL layers 116. By comparison, lower package layer 104 includes a molded package body 118, a die 120 embedded within body 118, and frontside RDL layers 122. As shown in FIG. 9, one or more solder balls 124 may provide electrical connection between interconnect lines provided within the neighboring RDL layers of the stacked packages layers; and, specifically, between backside interconnect lines 126 formed within backside RDL layers 114 of upper package layer 102 and frontside interconnect lines 128 formed within frontside RDL layers 122 of lower package layer 104. As indicated above, FIG. 9 and the other drawing figures are not drawn to scale and that certain elements may be enlarged (e.g., solder balls 114 and 124, SMD 130, and SMD 132 in FIG. 9) relative to other elements (e.g., RDL layers 112, 114, and 122 in FIG. 9) for the purposes of illustration. In addition to or in lieu of such a solder ball interconnection, one or more SMDs may also be utilized to provide electrical interconnection between stacked package layers 102 and 104 of SiP 100, as described below.

With continued reference to FIG. 9, SiP 100 further includes a first vertically-oriented SMD 130 and a second horizontally-oriented SMD 132. SMDs 130 and 132 may be similar to SMD 28 and 34, respectively, described above in conjunction with FIGS. 1-8. In particular, SMDs 130 and 132 may each be a discrete chip resistor, capacitor, inductor, or diode having opposing electrically-conducive end terminals. However, in contrast to SMDs 28 and 34 (FIGS. 1-8), SMDs 130 and 132 extend between stacked package layers 102 and 104. For example, as shown in FIG. 9, SMDs 130 and 132 may each extend from frontside RDL layers 122 of lower package layer 104, across a gap 142 separating layers 102 and 104, and to backside RDL layers 116 of upper package layer 102. Gap 142 may or may not be filled with a dielectric underfill material. Bodies of electrically-conductive paste or adhesive 144 (e.g., globs of a silver-filled or copper-filled epoxy) may be deposited between the SMD terminals and the regions of interconnect lines 126 and 128 to which the SMD terminals are electrically coupled. For example, as shown in FIG. 9, RDL layers 114 and 122 may be patterned to form openings exposing regions of interconnect lines 126 and 128; and the openings may be filled with electrically-conductive paste to electrically interconnect the SMD terminals to selected interconnect lines embedded within RDL layers 114 and 122. In the illustrated embodiment, specifically, a terminal 134 of vertically-oriented SMD 130 is electrically coupled to electrically-conductive structure (e.g., an interconnect line 126) in backside RDL layers 116 of upper package layer 102, while an opposing terminal 136 of SMD 130 is electrically coupled to an electrically-conductive structure (e.g., an interconnect line 128) in frontside RDL layers 122 of lower package layer 104. By comparison, both terminals 138 and 140 of horizontally-oriented SMD 132 are electrically coupled to interconnect lines 126 and 128 provided in backside RDL layers 116 and in frontside RDL layers 122, respectively. In further embodiments, SMDs 130 and 132 may be utilized to provide electrical interconnection between other electrically-conductive structures included within stacked package layers 102 and 104 in addition to or in lieu of interconnect lines 126 and 128, which are also considered electrically-conductive structures in the context of this document.

During fabrication of SiP 100, and by way of non-limiting example only, RDL layers 112 and 122 may be built-up over molded panels utilizing standard processes of the type described above, openings may be formed in layers 114 and 122 exposing selected regions of interconnects lines 126 and 128 utilizing known lithographical patterning techniques, and electrically-conductive globs of paste 144 may be deposited into the openings formed in layers 114 and 112. SMDs 130 and 132 may then be positioned on package layer 104 in their desired locations utilizing, for example, a pick-and-place tool such that the SMD terminals are placed in ohmic contact with paste bodies 144. Package layer 102 may then be stacked on package layer 104 with proper alignment to ensure that SMDs 130 and 132 extend into the openings formed in RDL layers 114. In a preferred embodiment, package layers 102 and 104 are stacked prior to singulation of the respective molded panels in which layers 102 and 104 are contained. After stacking of the molded panels containing layers 102 and 104, BGA 114 may be produced utilizing a bumping process. The stacked molded panels may then be singulated to yield the completed PoP SiP 100 shown in FIG. 9.

In view of its vertical orientation, SMD 130 may provide those functions described above in conjunction with SMD 28 (FIGS. 1-8). In particular, SMD 130 may provide a known resistance, capacitance, or inductance across package layers 102 and 104; or, in embodiments wherein SMD 130 comprises a resistor having a resistance of 0Ω or about 0Ω, SMD 130 may provide a low resistance signal path across the stacked package layers. Similarly, horizontally-oriented SMD 132 may provide those functions described above in conjunction with SMD 34 (FIGS. 1-8). For example, SMD 132 may provide a known resistance, capacitance, or inductance across contact points or nodes provided in backside RDL layers 116 of upper package layer 102, provided in frontside RDL layers 122 of lower package layer 104, or between contact points provided in both backside RDL layers 116 and frontside RDL layers 122. Additionally or alternatively, SMD 132 may provide low resistance signal paths between upper and lower package layers 102 and 104 across one or both of its electrically-conductive end terminals 138 and 140.

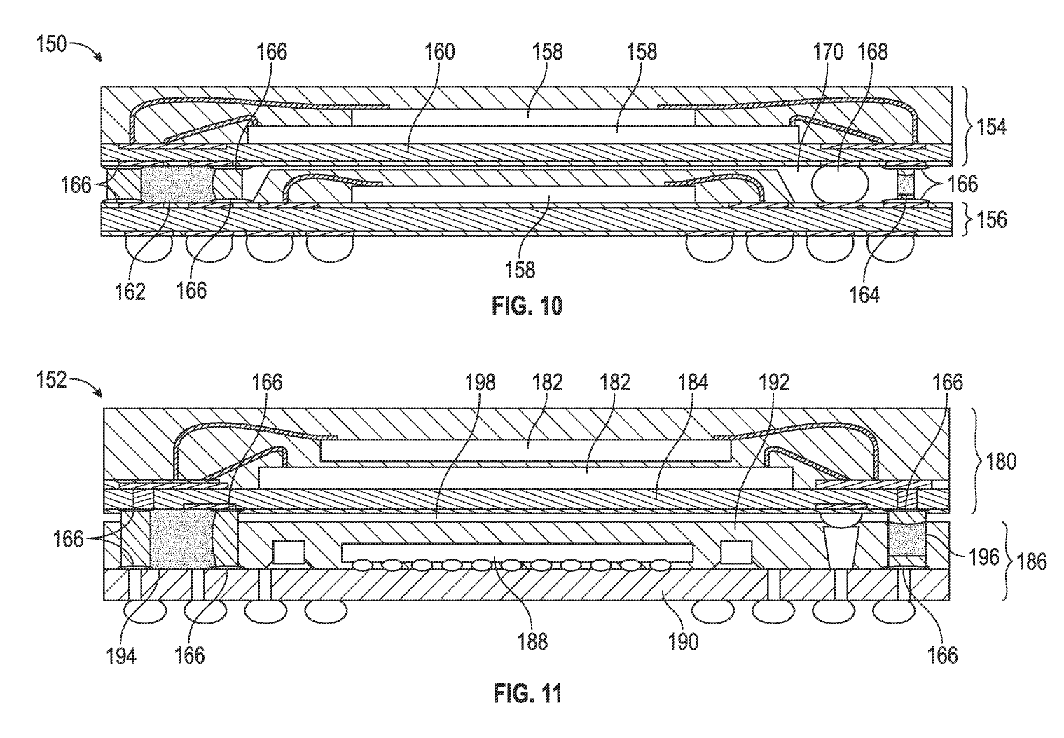

In further embodiments wherein the SiP includes one or more SMDs disposed between stacked package layers, one or more the stacked package layers may be produced utilizing a non-molded panel fabrication process, such as a Wafer Level Chip-Scale Packaging (WL-CSP), a Molded Array Process Ball Grid Array (MAPBGA), a Flip-Chip Ball Grid Array (FCBGA), or a sawn Quad-Flat No-Lead (QFN) strip level stacking process, to list but a few examples. Further emphasizing this point, FIGS. 10 and 11 illustrate two additional PoP SiPs (identified in FIGS. 10 and 11 as “150” and “152,” respectively), which may be produced in accordance with still further exemplary embodiments of the present invention. Addressing first PoP SiP 150 shown in FIG. 10, here the SiP includes two stacked package layers 154 and 156 produced utilizing a MAPBGA process. Package layers 154 and 156 each include at least one die 158 (the upper package layer 154 including two stacked die 158) wirebonded to bond pads provided on a laminate substrate 160. One or more horizontally-oriented SMDs 162 and one or more vertically-oriented SMDs 164 may be positioned between the stacked package layers 154 and 156; and, specifically, may be electrically coupled between the respective substrates 160 of layers 154 and 156. Again, bodies 166 of a metal-filled epoxy or another flowable electrically-conductive material may be deposited over the terminals of SMDs 164 and 166 to facilitate the desired electrical connections. One or more solder balls 168 may also provide additional electrical interconnection between the package layers 154 and 156. As shown in FIG. 10, SMDs 162 and 164 may extend across a gap 170 provided between package layers 154 and 156, which may or may not be filled with a dielectric underfill material. In one embodiment, SMDs 162 and 164 have a packaged height between about 200 and about 300 μm and which may be substantially equivalent to the height of solder balls 168, if included in SiP 150. In further embodiments, SMDs 162 and 164 may have packaged heights greater than or less than the aforementioned range.

Turning to FIG. 11, SiP 152 also includes a first stacked package layer 180, which may be produced in accordance with a MAPBGA process. As was the case previously, package layer 180 includes stacked die 182, which are wirebonded to conductors provided on a laminate substrate 184. However, in this case, SiP 152 further includes a second package layer 186 produced utilizing a so-called “Through-Mold-Via” or “TMV” packaging approach. Low package layer 186 includes a flip chip die 188, which is electrically interconnected to a substrate 190 and which is encapsulated in a dielectric body 192. One or more horizontally-oriented SMDs 194 and/or one or more vertically-oriented SMDs 196 may be positioned between the stacked package layers 180 and 186; and, specifically, may be electrically coupled between substrate 184 of upper package layer 180 and the substrate 190 of lower package layer 186. SMDs 194 and 196 extend into dielectric body 192 of lower package layer 186. Again, SMDs 194 and 196 may extend across a gap 198 may be provided between package layers 180 and 186, which may be left unfilled as an air gap or, instead, filled with a dielectric underfill material. In either case, SMDs 194 and 196 are considered embedded within SiP 152 in as much as SMDs 194 and 196 are disposed within SiP 152 and between the uppermost and lowermost surfaces thereof.

The foregoing has thus provided embodiments of a method for producing SiPs wherein SMDs, such as discrete resistors, capacitors, inductors, and/or diodes, are placed in ohmic contact with electrically-conductive members located on opposing sides of package body or located within different stacked package layers. The SMDs may be utilized to provide their traditional or intended function; e.g., the provision of a known resistance, capacitance, inductance, or the like. Additionally or alternatively, the embedded SMDs may also provide a new or heretofore unrealized function, namely, the provision of low (e.g., ˜0Ω) resistance signal paths through the package body and/or between package layers. In this manner, the embedded SMDs may effectively replace other structures or features traditionally utilized to provide signal routing through the package body (e.g., through package vias) and/or between package layers (e.g., solder balls). In certain cases, a single SMD may be utilized to provide both of these functionalities; e.g., a single chip resistor, capacitor, or inductor may provide a known resistance, capacitance, or inductance, respectively, while also providing one or more low resistance signal paths through the package body or between stacked package layers. The SMDs embedded within a given SiP may be positioned in horizontal orientations, vertical orientations, or a combination thereof. By embedding multiple SMDs in a molded package body in a vertical orientation, a greater number of SMDs can be integrated into the SiP while reducing the overall SiP footprint as compared to a similar SiP containing only horizontally-orientated SMDs.

In one embodiment of the above-described fabrication method, one or more frontside redistribution layers are produced over the frontside of a molded panel in which a semiconductor die and a first SMD embedded. The semiconductor die and the first SMD are exposed through the frontside of the molded panel. Material is removed from the backside of the molded panel to expose the first SMD therethrough. A contact array is formed over the frontside of the molded panel and electrically coupled to the semiconductor die and to the first SMD through the frontside redistribution layers. The molded panel is singulated to produce a SiP having a molded body in which the semiconductor die and the first SMD are embedded and through which the first SMD extends.

In another embodiment of the fabrication method, an SiP is produced that includes a first package layer and a second package layer. A first SMD is embedded between the first package layer and the second package layer substrate such that the first SMD electrically interconnects an electrically-conductive feature (e.g., a first RDL interconnect line, a trace provided on a substrate, a via provided through a substrate, etc.) included within the first package layer to an electrically-conductive feature (e.g., a second RDL interconnect line, a trace provided on a substrate, a via provided through a substrate, etc.) included within the second package layer. In certain embodiment, the first package layer may comprises a molded package body over which one or more redistribution layers has been formed. In such embodiments, the electrically-conductive feature included within the first package layer may be an interconnect line formed in the redistribution layers, and the first SMD may be positioned to extend into the redistribution layers and ohmically contact the interconnect line. In other embodiments, the first package layer may further include a second SMD embedded within and extending through the molded package body. In still further embodiments, the first package layer may be a first substrate, wherein the second package layer may be a second package substrate, and the first SMD may be positioned in ohmic contact with the first and second substrate. The first SMD may include opposing end terminals, and the method may include depositing bodies of electrically-conductive paste (e.g., a silver-filled or copper-filled epoxy) between the opposing end terminals of the first SMD, the electrically-conductive feature included within the first package layer, and the electrically-conductive feature included within the second package layer.

Embodiments of a SiP have also been provided. In one embodiment, the SiP includes a molded package body having a frontside and a backside. One or more frontside redistribution layers are disposed over the molded package body, and a frontside contact array is disposed over the frontside redistribution layers. A first SMD, such as a discrete resistor, capacitor, inductor, or diode, is embedded in the molded package body. The first SMD extends from the frontside to the backside of the molded package body and is electrically coupled to the frontside contact array through the frontside redistribution layers. In certain embodiments, the SiP may further include one or more backside redistribution layers disposed over the backside of the molded package body. In such cases, the SMD may include a first terminal exposed through the frontside of the molded package body and in ohmic contact with an interconnect line contained within the frontside redistribution layers, and a second terminal exposed through the backside of the molded package body and in ohmic contact with an interconnect line contained within the backside redistribution layers. In further implementations, the first SMD may be a discrete resistor, capacitor, inductor, or diode.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention. It being understood that various changes may be made in the function and arrangement of elements described in an exemplary embodiment without departing from the scope of the invention as set-forth in the appended claims.

What is claimed is:

1. A method for fabricating a System-in-Package (SiP), comprising:
producing one or more frontside redistribution layers over a molded panel having a backside and an opposing frontside through which a semiconductor die and a first Surface Mount Device (SMD) are exposed;
removing material from the backside of the molded panel to expose the first SMD therethrough;
forming a contact array over the frontside of the molded panel electrically coupled to the semiconductor die and to the first SMD through the frontside redistribution layers; and
singulating the molded panel to produce a SiP having a molded body in which the semiconductor die and the first SMD are embedded and through which the first SMD extends.

2. The method of claim 1 further comprising overmolding the semiconductor die and the first SMD with an encapsulant to produce the molded panel.

3. The method of claim 1 wherein removing material from the backside of the molded panel comprises planarizing the backside of the molded panel utilizing at least one of a chemical mechanical planarizing process and a grinding process.

4. The method of claim 3 wherein, after planarizing, the molded panel has a thickness between about 100 and about 1000 microns.

5. The method of claim 1 wherein the first SMD is selected from the group consisting of a resistor, a capacitor, an inductor, and a diode.

6. The method of claim 1 wherein the first SMD comprises a body having two opposing end terminals, wherein at least one of the end terminals is exposed through the frontside of the molded panel, and wherein at least one of the end terminals is exposed through the backside of the molded panel after removing material therefrom.

7. The method of claim 1 further comprising, after removing material from the backside of the molded panel to expose the first SMD therethrough, producing one or more backside redistribution layer over the backside of the molded panel in ohmic contact with the first SMD.

8. The method of claim 1 wherein the first SMD is vertically oriented within the molded panel.

9. The method of claim 8 wherein the height of the first SMD exceeds its width, the height of the first SMD taken along an axis orthogonal to the frontside of the molded body containing the first SMD, and the width of the first SMD taken along an axis parallel to the frontside of the molded body containing the first SMD.

10. The method of claim 8 wherein the first SMD comprises a resistor, which has a resistance of about 0 ohms and which provides a signal path across the molded body of the SiP.

11. The method of claim 1 wherein the first SMD is horizontally oriented within the molded panel.

12. The method of claim 11 wherein the first SMD comprises a first terminal providing a signal path through the molded body of the SiP.

13. The method of claim 11 further comprising a second SMD within the molded panel, the second SMD exposed along with the first SMD when the material is removed from the backside of the molded panel.

14. A method for fabricating a System-in-Package (SiP) including a first package layer and a second package layer, the method comprising:
positioning a first Surface Mount Device (SMD) between the first package layer and the second package layer substrate such that the first SMD electrically interconnects an electrically-conductive feature included within the first package layer to an electrically-conductive feature included within the second package layer.

15. The method of claim 14 wherein the first package layer comprises a molded package body over which one or more redistribution layers has been formed, wherein the electrically-conductive feature included within the first package layer comprises an electrically-conductive structure formed in the redistribution layers, and wherein the first SMD is positioned to extend to the redistribution layers and ohmically contact the electrically-conductive structure.

16. The method of claim 15 wherein the first package layer further comprises a second SMD embedded within and extending through the molded package body.

17. The method of claim 14 wherein the first package layer comprises a first substrate, wherein the second package layer comprises a second package substrate, and wherein the first SMD is positioned in ohmic contact with the first and second substrate.

18. The method of claim 14 wherein the first SMD comprises opposing end terminals, and wherein the method further comprises depositing bodies of electrically-conductive paste between the opposing end terminals of the first SMD, the electrically-conductive feature included within the first package layer, and the electrically-conductive feature included within the second package layer.

19. A System-in-Package (SiP), comprising:
a molded package body having a frontside and a backside;
one or more frontside redistribution layers disposed over the frontside of the molded package body;
a frontside contact array disposed over the frontside redistribution layers; and
a Surface Mount Device (SMD) embedded in the molded package body, the SMD extending from the frontside to the backside of the molded package body and electrically coupled to the frontside contact array through the frontside redistribution layers.

20. The SiP of claim 19 further comprising one or more backside redistribution layers disposed over the backside of the molded package body, and wherein the SMD comprises:
a first terminal exposed through the frontside of the molded package body and in ohmic contact with an interconnect line contained within the frontside redistribution layers; and
a second terminal exposed through the backside of the molded package body and in ohmic contact with an interconnect line contained within the backside redistribution layers.
